(19) United States
(12) Patent Application Publication
(10) Pub. No.: US 2016/0216313 A1
(43) Pub. Date: Jul. 28, 2016

(54) TRANSISTOR TESTING CIRCUIT AND METHOD THEREOF, SEMICONDUCTOR MEMORY APPARATUS AND SEMICONDUCTOR APPARATUS

(71) Applicant: Powerchip Technology Corporation, Hsinchu (TW)

(72) Inventor: Akira Ogawa, Tokyo (JP)

(21) Appl. No.: 14/741,463

(22) Filed: Jun. 17, 2015

(30) Foreign Application Priority Data
Jan. 22, 2015 (JP) 2015-010516

(51) Int. Cl. G01R 31/26

(52) U.S. Cl. CPC G01R 31/2623; G01R 31/2644

(57) ABSTRACT

A transistor testing circuit for measuring a breakdown voltage of a transistor included in a semiconductor apparatus with high accuracy for each chip is provided. The transistor testing circuit is disposed on a semiconductor chip to measure the breakdown voltage of a MOS transistor. The transistor testing circuit includes: a voltage applying apparatus, a current detecting circuit, a current mirror voltage outputting circuit, and a comparator circuit. The voltage applying apparatus applies a predetermined testing voltage to at least one of a drain, a source, and a gate of the MOS transistor. When the testing voltage is applied, the current detecting circuit detects a current flowing from the MOS transistor to a load circuit. The current mirror voltage outputting circuit generates a mirror current corresponding to the detected current and outputs the same. The comparator circuit compares the mirror current with a predetermined reference current to output a comparison result signal.

### CROSS-REFERENCE TO RELATED APPLICATION

This application claims the priority benefit of Japan application serial no. 2015-010516, filed on Jan. 22, 2015. The entirety of the above-mentioned patent application is hereby incorporated by reference herein and made a part of this specification.

### BACKGROUND OF THE INVENTION

1. Field of the Invention

The invention relates to a transistor testing circuit and a transistor testing method for testing a transistor, such as a metal-oxide-semiconductor (MOS) transistor, by evaluating a breakdown voltage of the transistor, a semiconductor memory apparatus including the transistor testing circuit, and a semiconductor apparatus including the transistor testing circuit.

2. Description of Related Art

Flash memories, such as NAND type flash memory or NOR type flash memory, require a high voltage (HV) for programming (writing data) or erasing data. In an example, a high voltage of maximum 30V is used. For example, a high voltage of maximum 25V is applied to a gate of a memory cell transistor.

FIG. 2 is a circuit diagram showing a configuration example of a row decoder 22 of the conventional NAND type flash memory. In FIG. 2, the row decoder 22 includes a high voltage outputting circuit, which includes MOS transistors Q1-Q6 for outputting a high voltage Vpp (e.g. 30V) for programming or erasing data to the gates of word line driver transistors WD0-WD31. Moreover, in FIG. 2, HVND represents a normally depletion type N channel MOS transistor; HVNd1 and HVNds represent offset gate type N channel MOS transistors; Vww represents a write voltage of 25V, for example; WP is a write control power source voltage; SELB is a select signal; and WLEN is a word line enable signal. The same applies to the following descriptions.

### PRIOR ART LITERATURE

### Patent Literature

Patent Literature 1: Japanese Patent Publication No. H10-178073
Patent Literature 2: Japanese Patent Publication No. 2003-307549
Patent Literature 3: Specification of US Patent Publication No. 2012/0074973

However, the maximum voltage of the high voltage is lower than the breakdown voltage (V_BD) of the high voltage transistor by about 2V to 3V, which does not provide a sufficient margin. Thus, due to process variations, the start voltage of the programming or erasing may rise or the breakdown voltage may drop and result in low yield, or the transistor quality may deteriorate due to repeated breakdown resulting from repeated programming and erasing, which causes field failure of programming and erasing.

Generally, the performance of the high voltage transistor is inspected at a quality checking transistor formed on a scribe line. However, the inspection is not performed on all lots and all wafers. The maximum value of the high voltage used by the semiconductor chip that has passed the wafer test may exceed the breakdown voltage. In other words, the wafer test is a checkpoint used for excluding defective semiconductor chips that do not meet the performance requirements. However, the following problem exists. That is, the maximum value of the high voltage used by the semiconductor chip is not set based on the breakdown voltage of the transistor in each semiconductor chip.

Moreover, in Patent Literature 1 and Patent Literature 3, only the inspection area (Test Element Group) is installed on the semiconductor chip. Although the performance of the transistor corresponding to each semiconductor chip can be checked, it requires connection to an external device that has a current voltage measurement member. As a result, the measurement takes more time. Besides, it is not possible to test the performance of thousands or hundreds of thousands of transistors in the semiconductor chip.

### SUMMARY OF THE INVENTION

The invention is made in view of the above. By a transistor testing circuit that tests a transistor disposed in a semiconductor apparatus, the invention provides a transistor testing circuit and a method thereof for measuring and estimating a breakdown voltage of the transistor included in the semiconductor apparatus with high precision, and a semiconductor memory apparatus and a semiconductor apparatus that may measure and estimate a breakdown voltage of the transistor included in the semiconductor apparatus with high precision.

A transistor testing circuit of an embodiment of the invention is disposed on a semiconductor chip for measuring a breakdown voltage of a MOS transistor. The transistor testing circuit includes:

a voltage applying apparatus applying a predetermined testing voltage to at least one of a drain, a source, and a gate of the MOS transistor;
a current detecting circuit detecting a detecting current flowing from the MOS transistor to a load circuit when the testing voltage is applied; and
a current mirror voltage outputting circuit generating a mirror current corresponding to the detecting current and outputting the mirror current.

The transistor testing circuit further includes: a comparator circuit comparing the mirror current with a predetermined reference current and outputting a comparison result signal.

The transistor testing circuit further includes: a test pad outputting the mirror current to an external circuit.

In the transistor testing circuit, the current mirror voltage outputting circuit generates the mirror current corresponding to the detecting current in a ratio of N:1 (N is 1 or more) and outputs the mirror current.

The transistor testing circuit further includes: a switch circuit connecting at least one of a plurality of transistor terminals including the source, the drain, the gate, a well tap, and a substrate tap of the MOS transistor to the load circuit.

The switch circuit applies a predetermined applying voltage to at least one of the transistor terminals not connected to the load circuit.

The applying voltage is a predetermined value or a ground voltage.

In the transistor testing circuit, the load circuit is a load resistor, a diode-connected depletion type MOS transistor, an enhancement type MOS transistor applied with a predetermined gate voltage, or a depletion type MOS transistor applied with a predetermined gate voltage.

The transistor testing circuit further includes: a high voltage protection circuit inserted between the MOS transistor and the load circuit.

Here, in the transistor testing circuit, the high voltage protection circuit includes: a depletion type MOS transistor having a high voltage withstand voltage; and an enhancement type MOS transistor applied with a predetermined gate voltage.

The transistor testing circuit further includes: a level shifter operating in response to a predetermined testing signal to output or not output a predetermined high voltage as the testing voltage.

A transistor testing circuit of an embodiment of the invention is disposed between a current detecting node of a predetermined test object circuit of a semiconductor chip and a ground node for measuring a breakdown voltage of the test object circuit. The transistor testing circuit includes:

a voltage applying apparatus applying a predetermined testing voltage to the test object circuit;
a current detecting circuit detecting a detecting current flowing from the test object circuit to a load circuit when the testing voltage is applied; and
a current mirror voltage outputting circuit generating a mirror current corresponding to the detecting current and outputting the mirror current.

The transistor testing circuit further includes: a comparator circuit comparing the mirror current with a predetermined reference current and outputting a comparison result signal.

The transistor testing circuit further includes: a test pad outputting the mirror current to an external circuit.

The transistor testing circuit further includes: a switch member selectively switching to connect or not connect the current detecting node to the load circuit.

In the transistor testing circuit, the test object circuit is a row decoder.

Here, the current detecting node is connected to at least one of a ground-side power source line of the row decoder, and a substrate tap or a well tap of the row decoder.

In the transistor testing circuit, the test object circuit is a word line driver.

Here, the current detecting node is connected to at least one of a source, a substrate tap, and a well tap of a MOS transistor of the test object circuit.

In the transistor testing circuit, the load circuit is a load resistor, a diode-connected depletion type MOS transistor, an enhancement type MOS transistor applied with a predetermined gate voltage, or a depletion type MOS transistor applied with a predetermined gate voltage.

The transistor testing circuit further includes: a high voltage protection circuit inserted between the current detecting node and the load circuit.

Here, the high voltage protection circuit includes: a depletion type MOS transistor having a high voltage withstand voltage; and an enhancement type MOS transistor applied with a predetermined gate voltage.

A semiconductor memory apparatus of an embodiment of the invention includes the transistor testing circuit.

A semiconductor apparatus of an embodiment of the invention includes the transistor testing circuit.

A transistor testing method of an embodiment of the invention is executed by a transistor testing circuit that is disposed on a semiconductor chip for measuring a breakdown voltage of a MOS transistor. The transistor testing method includes the following steps:

applying a predetermined testing voltage to at least one of a drain and a gate of the MOS transistor;
detecting a detecting current flowing from the MOS transistor to a load circuit when the testing voltage is applied; and
generating a mirror current corresponding to the detecting current and outputting the mirror current.

The transistor testing method further includes: comparing the mirror current with a predetermined reference current and outputting a comparison result signal.

The transistor testing method further includes: outputting the mirror current to an external circuit via a testing tap.

Therefore, according to the transistor testing circuit of the invention, by the transistor testing circuit that tests the transistor disposed in the semiconductor apparatus, the transistor testing circuit and the method thereof for measuring and estimating the breakdown voltage of the transistor included in the semiconductor apparatus with high precision, and the semiconductor memory apparatus and the semiconductor apparatus which may measure and estimate the breakdown voltage of the transistors included in them with high precision, are provided.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 is a block diagram showing a configuration of the non-volatile memory apparatus of Embodiment 1 of the invention.

FIG. 2 is a circuit diagram showing a configuration example of the row decoder 22 of the conventional NAND type flash memory.

FIG. 3 is a circuit diagram showing a configuration of the transistor testing circuit of Embodiment 1.

FIG. 4 is a diagram showing an operation of the transistor testing circuit of FIG. 3.

FIG. 5A(a) to FIG. 5A(e) show configuration examples of the measured transistor circuit 51 of the transistor testing circuit of Embodiment 2. FIG. 5A(a) is a circuit diagram showing a configuration example of the measured transistor circuit 51a of Working example 1. FIG. 5A(b) is a circuit diagram showing a configuration example of the measured transistor circuit 51b of Working example 2. FIG. 5A(c) is a circuit diagram showing a configuration example of the measured transistor circuit 51c of Working example 3. FIG. 5A(d) is a circuit diagram showing a configuration example of the measured transistor circuit 51d of Working example 4. FIG. 5A(e) is a circuit diagram showing a configuration example of the measured transistor circuit 51e of Working example 5.

FIG. 5B is a vertical cross-sectional view showing the structure of the MOS transistor of the measured transistor circuit 51c of FIG. 5A(c).

FIG. 5C is a plan view showing the structure of the MOS transistor of the measured transistor circuit 51c of FIG. 5A(c).

FIG. 5D is a vertical cross-sectional view along the line A-A′ of FIG. 5C.

FIG. 6 is a circuit diagram showing a configuration example of the combined switching type measured transistor circuit 51A of the transistor testing circuit of Embodiment 2.

FIG. 7A is a circuit diagram showing a configuration example of the measured transistor circuit 51 with the high voltage level shifter 61 of Embodiment 3.

FIG. 7B is a circuit diagram showing a configuration example of the measured transistor circuit 51 with the high voltage level shifters 61 and 62 of the modified example of Embodiment 3.

FIG. 8 is a circuit diagram showing a configuration example of the high voltage level shifters 61 and 62 of FIG. 7A and FIG. 7B.

FIG. 9 is a voltage table showing an operation of the measured transistor circuit 51 of FIG. 7A and FIG. 7B.

FIG. 10 is a circuit diagram showing a configuration example of the transistor testing circuit of Embodiment 4.

FIG. 11 is a diagram showing a measuring method of the breakdown voltage of the transistor testing circuit of FIG. 10.

FIG. 12 is a block diagram showing a configuration example of the word line driver of the NOR type flash memory of Embodiment 5.

FIG. 13 is a power source voltage table showing an operation of the word line driver of FIG. 12.

FIG. 14 is a circuit diagram showing a configuration example of the transistor testing circuit of the word line driver of FIG. 12.

FIG. 15 is a flowchart showing a monitoring and testing process in the wafer test of Embodiment 6.

FIG. 16 is a circuit diagram showing a configuration example of the transistor testing circuit of Embodiment 7.

FIG. 17 is a circuit diagram showing a configuration example of the transistor testing circuit of Embodiment 8.

FIG. 18 is a circuit diagram showing a configuration example of the transistor testing circuit of Embodiment 9.

FIG. 19 is a circuit diagram showing a configuration example of the transistor testing circuit of Embodiment 10.

FIG. 20A is a circuit diagram showing a configuration example of the current mirror circuit 58 of FIG. 3, FIG. 16, and FIG. 19.

FIG. 20B is a circuit diagram showing a configuration example of the current mirror circuit 58A of Modified Example 1.

FIG. 20C is a circuit diagram showing a configuration example of the current mirror circuit 58B of Modified Example 2.

FIG. 20D is a circuit diagram showing a configuration example of the current mirror circuit 58C of Modified Example 3.

### DESCRIPTION OF THE EMBODIMENTS

Embodiments of the invention are described hereinafter with reference to the figures. In the following embodiments, identical components/elements are assigned with the same reference numerals.

### Embodiment 1

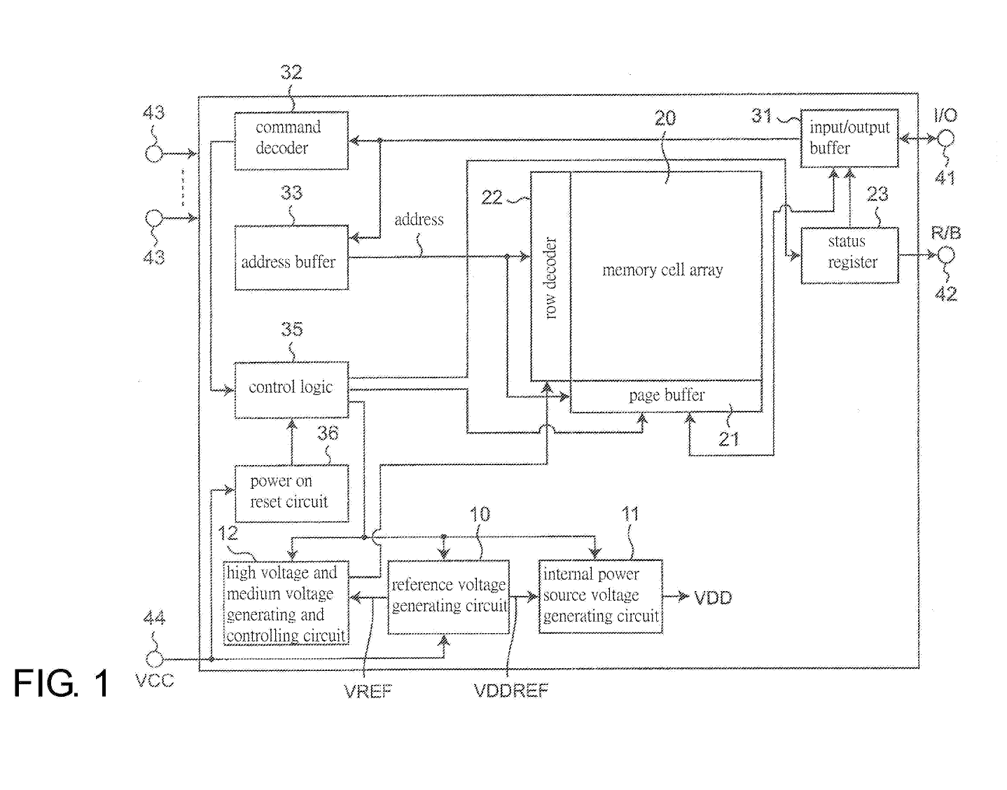

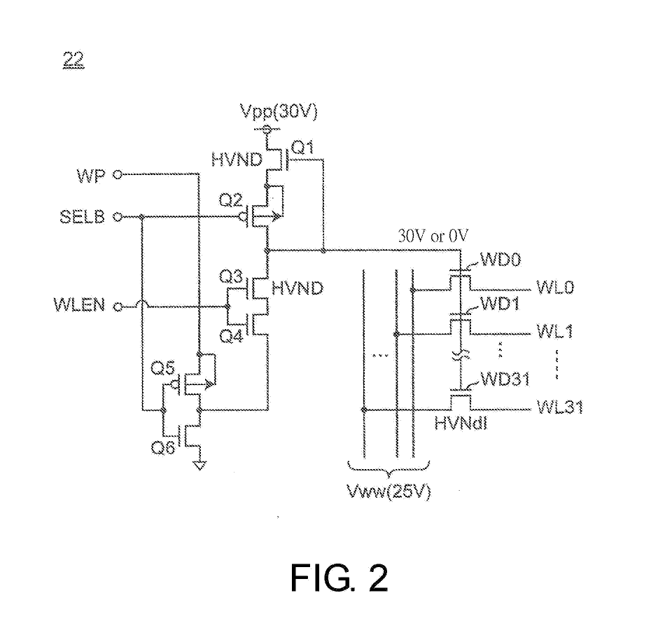

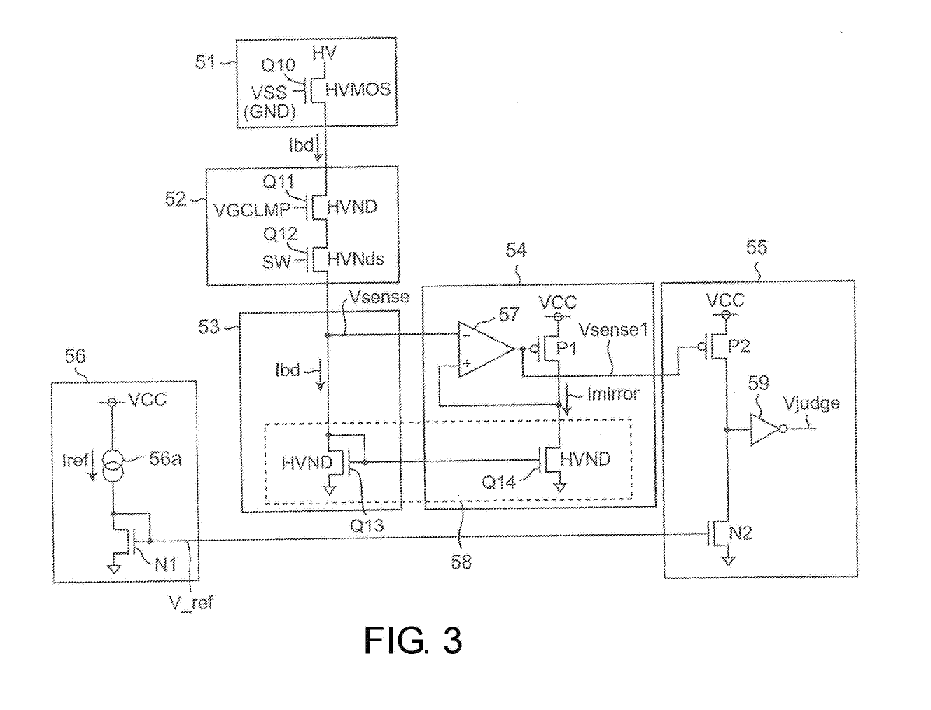

FIG. 1 is a block diagram showing a configuration of a non-volatile memory apparatus of Embodiment 1 of the invention. The non-volatile memory apparatus of Embodiment 1 is a NAND type flash memory, for example, which is characterized in serving a transistor testing circuit as a peripheral circuit of a row decoder 22. As shown in FIG. 3, the transistor testing circuit for measuring a breakdown voltage of a high voltage transistor Q10 is installed on a memory chip.

In FIG. 1, the non-volatile memory apparatus includes:

(1) a memory cell array 20, which serves as a flash memory array, for example, for storing data;
(2) a page buffer 21, which writes data from an input/output buffer 31 to the memory cell array 20 based on a page as a unit, or reads data from the memory cell array based on a page as a unit and outputs the data to the input/output buffer 31;
(3) a row decoder 22, which specifies a block and a word line of the memory cell array 20 in response to a specified address;
(4) a status register 23, which temporarily stores a status of the non-volatile memory apparatus according to a signal from a control logic 35 and outputs the same to the input/output buffer 31, and generates a ready/busy signal (RIB signal) and outputs the same to a R/B signal terminal 42;
(5) the input/output buffer 31, which temporarily stores data inputted/outputted via an input/output terminal 41;
(6) a command decoder 32, which decodes a command from the input/output buffer 31 to output decoded command data to the control logic 35;
(7) an address buffer 33, which temporarily stores the specified address from the input/output buffer 31;
(8) a power on reset circuit 36, which outputs a reset signal for resetting an operation of a semiconductor chip when the power is on based on an external power source voltage VCC;
(9) a reference voltage generating circuit 10, which generates a predetermined internal power source voltage reference voltage VDDREF and a predetermined reference voltage VREF based on the external power source voltage VCC applied via an external power source voltage terminal 44;
(10) an internal power source voltage generating circuit 11, which generates an internal power source voltage VDD based on the reference voltage VDDREF and supplies the same to each circuit;
(11) a high voltage and medium voltage generating and controlling circuit 12, which generates and outputs a high voltage (HV) and a medium voltage (MV) for data writing (programming) and erasing based on the reference voltage VREF; and
(12) the control logic 35, which performs a predetermined control on each circuit (including the reference voltage generating circuit 10, the internal power source voltage generating circuit 11, the high voltage and medium voltage generating and controlling circuit 12, the page buffer 21, and the status register 23) in the non-volatile memory apparatus based on the command data from the command decoder 32, the control signal inputted via the control signal terminal 43, and/or the reset signal from the power on reset circuit 36.

FIG. 3 is a circuit diagram showing a configuration of the transistor testing circuit of Embodiment 1. In FIG. 3, the transistor testing circuit is provided with a measured transistor circuit 51, a high voltage protection circuit 52, a current detecting circuit 53, a current mirror voltage outputting circuit 54, a comparator circuit 55, and a reference bias current generating circuit 56.

The measured transistor circuit 51 is installed on the semiconductor chip of the non-volatile memory apparatus and includes a MOS transistor Q10 to be used as a measured object replica. The MOS transistor Q10 is manufactured based on the same manufacturing processes as a high voltage operation MOS transistor (HVMOS) and is installed on the semiconductor chip. Here, the setting is that: a predetermined testing high voltage HV from the high voltage and medium voltage generating and controlling circuit 12 of FIG. 1 is applied to the drain of the MOS transistor Q10, and a voltage VSS of a ground voltage is applied to the gate, for example. The MOS transistor Q10 is tested in the wafer test, and based on the test result, an optimal maximum value of the high voltage is decided as described hereinafter. The high voltage protection circuit 52 includes two MOS transistors Q11 and Q12 that are connected in series and is disposed in order to protect the transistor testing circuit from damage caused by the high voltage. Here, the MOS transistor Q11 is a depletion type transistor having a high withstand voltage, and the MOS transistor Q12 is an enhancement type transistor applied with a predetermined gate voltage SW, for example.

The current detecting circuit 53 includes a MOS transistor Q13, i.e. a diode-connected load circuit, for detecting a current Ibd that flows through the high voltage protection circuit 52 from the measured transistor circuit 51. The current mirror voltage outputting circuit 54 includes a differential amplifier 57, formed by an operational amplifier, and MOS transistors P1 and Q14, for example. The differential amplifier 57 constitutes a voltage follower circuit for detecting a voltage Vsense generated by the current Ibd flowing to the current detecting circuit 53, generating a control voltage Vsense1 that is applied to the gate of the MOS transistor P1 to make the drain voltage of the MOS transistor P1 equal to Vsense such that a mirror current Imirror corresponding to the current Ibd flows, and outputting the control voltage Vsense1 from the output terminal of the differential amplifier 57 to the gate of a MOS transistor P2 of the comparator circuit 55. Here, the depletion type MOS transistors Q13 and Q14 constitute a current mirror circuit 58. If a ratio of the sizes of the MOS transistors Q13 and Q14 is 1:1, the mirror current Imirror satisfying Imirror=Ibd flows; and if the ratio of the sizes of the MOS transistors Q13 and Q14 is 1:N, the mirror current Imirror satisfying Imirror=N×Ibd flows. Thereby, Ibd of tens of nA is set as Imirror of hundreds of nA to several μA, for example.

The reference bias current generating circuit 56 includes a reference current source 56a that makes a reference current Iref flow and a diode-connected MOS transistor N1, and generates the reference current Iref to generate a reference voltage V_ref corresponding to the reference current Iref. The comparator circuit 55 includes MOS transistors P2 and N2 and an inverter 59 for comparing the current corresponding to the current Ibd mirrored by the MOS transistor P2 based on the control voltage Vsense1 with the current corresponding to the reference current Iref mirrored by the MOS transistor N2 based on the reference voltage V_ref, and using the inverter 59 to invert a binary digital signal that serves as the comparison result and outputting the same as a comparison result signal Vjudge. In addition, the reference current Iref is set corresponding to the breakdown voltage V_BD.

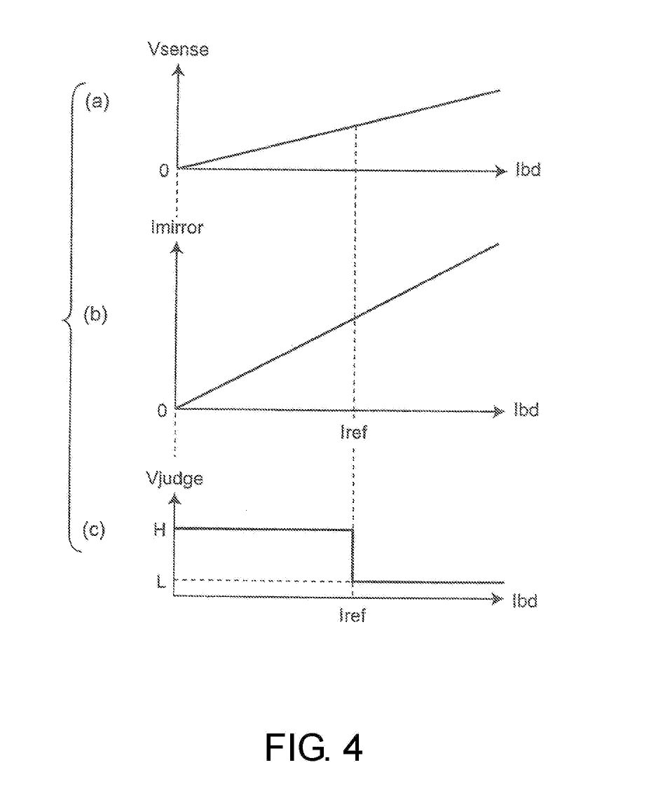

FIG. 4 is a diagram showing an operation of the transistor testing circuit of FIG. 3. As shown in FIG. 4, the detecting voltage Vsense and the mirror current Imirror increase in proportion to the current Ibd flowing in the MOS transistor Q10 of the measured transistor circuit 51. If the value of the current Ibd exceeds the reference current Iref, the comparator circuit 55 switches the comparison result signal Vjudge from a predetermined high level to a predetermined low level and outputs the same. Of course, the value of the current Ibd for the switching of the output level of the comparator may be set to be N times or 1/N times the reference current Iref based on a mirror ratio of each current mirror in the circuit (N≧1).

As described above, the drain of the MOS transistor Q10 of the measured transistor circuit 51 is applied with the predetermined high voltage HV, the current detecting circuit 53 and the current mirror voltage outputting circuit 54 are used to measure the source current Ibd thereof, and the comparator circuit 55 is used to compare the current mirrored based on the control voltage Vsense1 and corresponding to the current Ibd with the current mirrored based on the reference voltage V_ref and corresponding to the reference current Iref and thereby compare the detected source current Ibd with the reference current Iref, so as to obtain the comparison result signal Vjudge for measuring and estimating the breakdown voltage V_BD.

Moreover, in order to maintain the detecting voltage Vsense about 0V, depletion MOS type transistors Q13 and Q14 are used to constitute the current mirror circuit 58.

### Embodiment 2

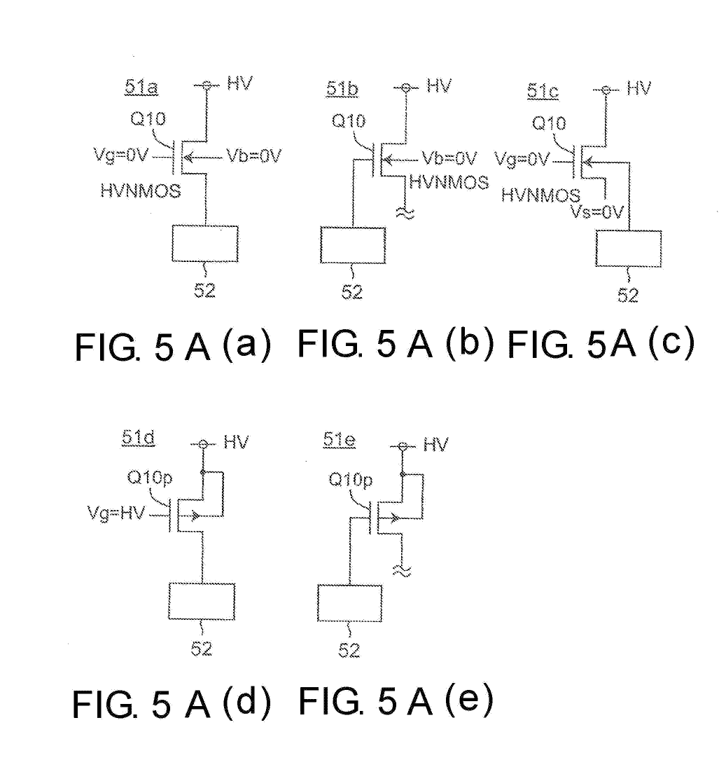

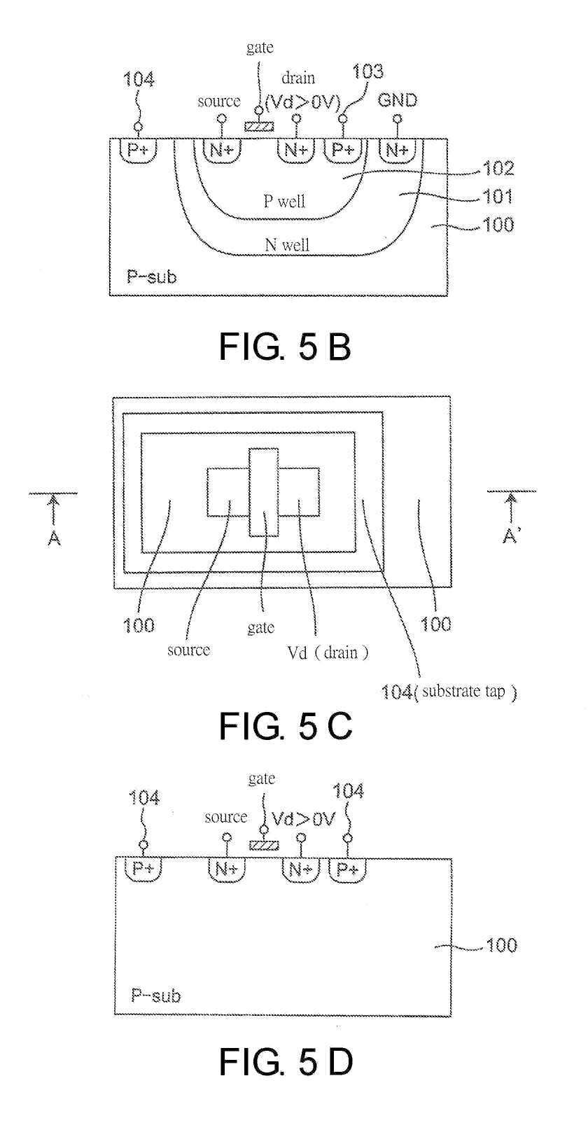

FIG. 5A(a) to FIG. 5A(e) show configuration examples of the measured transistor circuit 51 of the transistor testing circuit of Embodiment 2. FIG. 5A(a) is a circuit diagram showing a configuration example of the measured transistor circuit 51a of Working example 1. FIG. 5A(b) is a circuit diagram showing a configuration example of the measured transistor circuit 51b of Working example 2. FIG. 5A(c) is a circuit diagram showing a configuration example of the measured transistor circuit 51c of Working example 3. FIG. 5A(d) is a circuit diagram showing a configuration example of the measured transistor circuit 51d of Working example 4. FIG. 5A(e) is a circuit diagram showing a configuration example of the measured transistor circuit 51e of Working example 5. Further, FIG. 5B is a vertical cross-sectional view showing the structure of the MOS transistor of the measured transistor circuit 51c of FIG. 5A(c). FIG. 5C is a plan view showing the structure of the MOS transistor of the measured transistor circuit 51c of FIG. 5A(c). FIG. 5D is a vertical cross-sectional view along the line A-A′ of FIG. 5C.

In Embodiment 2, the circuit for respectively measuring various breakdown voltages V_BD of the MOS transistor Q10 of the measured transistor circuit 51 is described as follows.

(Measurement A) In FIG. 5A(a) showing the same configuration as the measured transistor circuit 51 of Embodiment 1, when the gate voltage Vg satisfies Vg=0V, the transistor testing circuit of Embodiment 1 is used to measure the current Ibd, i.e. the punch through current or the drain/source current generated by the substrate current effect.

(Measurement B) In FIG. 5A(b), the transistor testing circuit of Embodiment 1 is used to measure the drain-gate current.

(Measurement C) In FIG. 5A(c) showing the MOS transistor having the configuration of FIG. 5B, FIG. 5C, and FIG. 5D, the transistor testing circuit of Embodiment 1 is used to measure a junction leakage current (gate-induced-drain leakage (GIDL) current, which refers to that when a reverse bias voltage is applied from the source to the gate, the drain current flows even without the gate voltage Vg) and the drain-substrate current that flows due to band-to-band tunneling, impact ionization, and so on. Here, for the substrate terminal, there are the following two situations.

(Measurement C-1) A P well tap 103 in the triple well structure of FIG. 5B is set as the substrate terminal. In FIG. 5B, in a P type silicon substrate 100, an N well 101 is formed by implanting an N type dopant, e.g. phosphorus, for example. Besides, a P well 102 is formed by implanting a P type dopant, e.g. boron, into an upper side of the N well 101, thereby forming the P well tap 103. That is, in FIG. 5B, the MOS transistor, as the measured object, includes a plurality of transistor terminals, i.e. the source, the drain, the gate, the well tap (the P well tap 103, etc.), and the substrate tap 104.

(Measurement C-2) The substrate tap 104 of the P type silicon substrate 100 of the MOS transistor in FIG. 5D may be set as the substrate terminal, for example. In FIG. 5D, the substrate tap is disposed to surround the transistor that is the measured object, and a large portion of the current, which flows into the substrate due to the breakdown generated in the transistor that is the measured object, can be detected through the substrate tap by using the current detecting circuit.

(Measurement D) In FIG. 5A(d), the transistor testing circuit of Embodiment 1 is used to measure the drain current of a PMOS transistor Q10p, and the gate, the source, and the substrate of the PMOS transistor Q10p are applied with the high voltage HV.

(Measurement E) In FIG. 5A(e), the transistor testing circuit of Embodiment 1 is used to measure the current of the gate of the PMOS transistor Q10p, and the PMOS transistor Q10p has the source and the substrate applied with the high voltage HV.

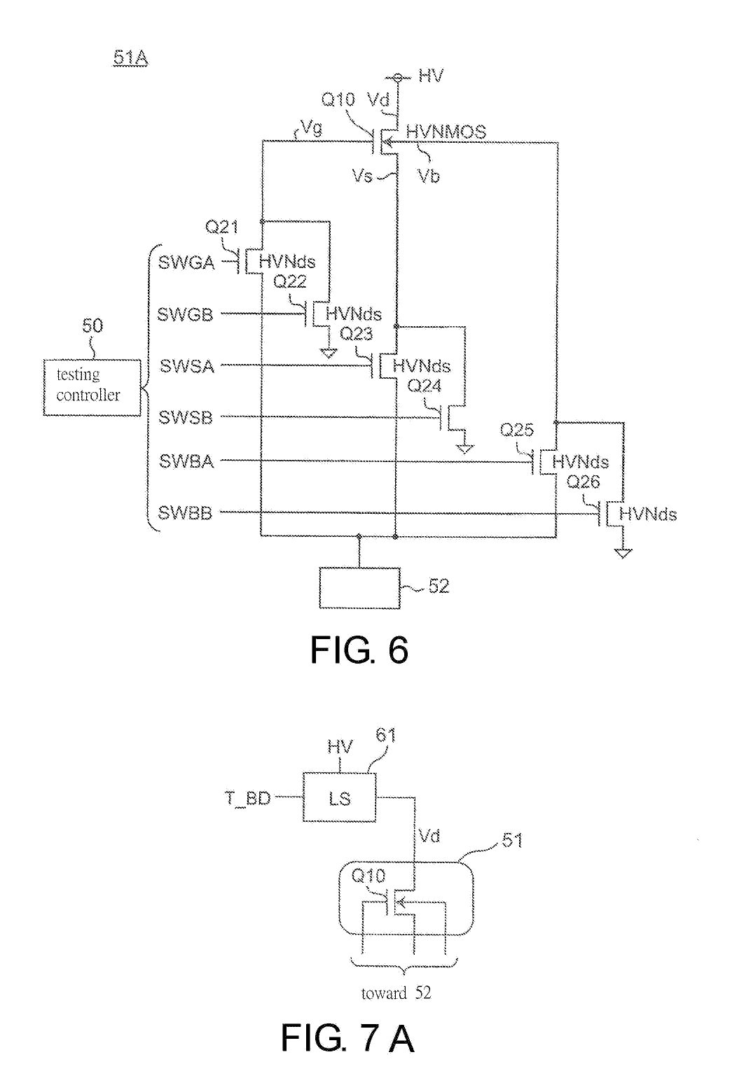

FIG. 6 is a circuit diagram showing a configuration example of the combined switching type measured transistor circuit 51A of the transistor testing circuit of Embodiment 2.

In the measured transistor circuit 51A of FIG. 6:

(1) The gate of the measured MOS transistor Q10 is connected to the high voltage protection circuit 52 via a switching MOS transistor Q21 controlled based on a switching control signal SWGA, and is grounded via a switching MOS transistor Q22 controlled based on a switching control signal SWGB.
(2) The source of the measured MOS transistor Q10 is connected to the high voltage protection circuit 52 via a switching MOS transistor Q23 controlled based on a switching control signal SWSA, and is grounded via a switching MOS transistor Q24 controlled based on a switching control signal SWSB.
(3) The substrate tap of the measured MOS transistor Q10 is connected to the high voltage protection circuit 52 via a switching MOS transistor Q25 controlled based on a switching control signal SWBA, and is grounded via a switching MOS transistor Q26 controlled based on a switching control signal SWBB.

Here, the switching control signals SWGA, SWGB, SWSA, SWSB, SWBA, and SWBB are inputted from a testing controller 50 installed on the semiconductor chip or an external testing device, for example. In the Measurement A, the MOS transistors Q22, Q23, and Q26 are set to ON and the other MOS transistors Q21, Q24, and Q25 are set to OFF, so as to measure the source-drain current of the measured MOS transistor Q10. In the Measurement B, the MOS transistors Q21 and Q26 are set to ON and the other MOS transistors Q22, Q23, Q24, and Q25 are set to OFF, so as to measure the drain-gate current of the measured MOS transistor Q10. Further, in the Measurement C, the MOS transistors Q22, Q24, and Q25 are set to ON and the other MOS transistors Q21, Q23, and Q26 are set to OFF, so as to measure the drain-substrate current of the measured MOS transistor Q10. Moreover, the measurement of the current value and the measurement of the breakdown voltage V_BD are the same as Embodiment 1.

As explained above, according to Embodiment 2, with respect to the measured MOS transistor Q10, the breakdown voltage V_BD based on three kinds of currents can be measured.

### Embodiment 3

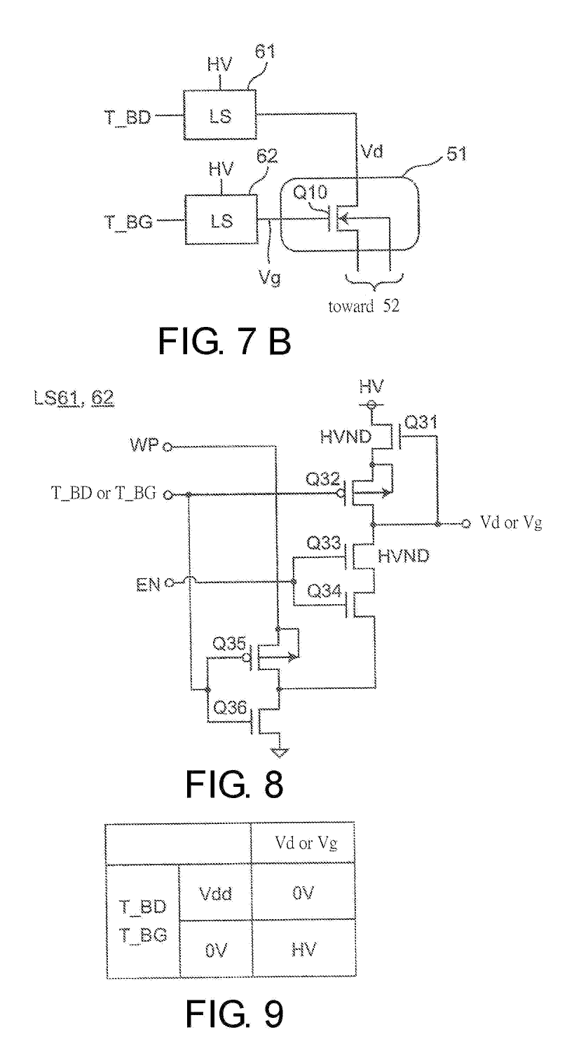

FIG. 7A is a circuit diagram showing a configuration example of the measured transistor circuit 51 with the high voltage level shifter 61 of Embodiment 3.

In the measurement of the breakdown voltage V_BD of the measured MOS transistor Q10 of the measured transistor circuit 51, the measured MOS transistor Q10 may be damaged. If damage occurs, even in a user mode other than the test mode, unexpected current flow may occur due to application of the drain voltage and the gate voltage, which should be avoided. In this embodiment, the high voltage HV is applied via the high voltage level shifter 61 controlled according to a testing signal T_BD, so as to prevent the aforementioned phenomenon. In FIG. 7A, the high voltage level shifter 61 is turned on or off in response to the testing signal T_BD, so as to perform control by applying or not applying the predetermined high voltage HV to the drain of the MOS transistor Q10.

FIG. 7B is a circuit diagram showing a configuration example of the measured transistor circuit 51 with the high voltage level shifter 61 of the modified example of Embodiment 3. In comparison with the configuration example of FIG. 7A, the configuration example of FIG. 7B further includes a high voltage level shifter 62. In FIG. 7B, the high voltage level shifter 61 is turned on or off in response to the testing signal T_BD, so as to perform control by applying or not applying the predetermined high voltage HV to the drain of the MOS transistor Q10. Moreover, the high voltage level shifter 62 is turned on or off in response to the testing signal T_BG, so as to perform control by applying or not applying the predetermined high voltage HV to the gate of the MOS transistor Q10. Accordingly, the gate is applied with the high voltage for measuring the source current or the substrate current, thereby detecting the breakdown voltage caused by defects of the gate insulating film.

FIG. 8 is a circuit diagram showing a configuration example of the high voltage level shifters 61 and 62 of FIG. 7A and FIG. 7B. In FIG. 8, the high voltage level shifters 61 and 62 include MOS transistors Q31 and Q32 that constitute the level shifters, MOS transistors Q33 and Q34 that constitute the high voltage protection circuit, and MOS transistors Q35 and Q36 that constitute the enable switching inverter. Here, WP is a predetermined power source voltage and EN is an enable signal.

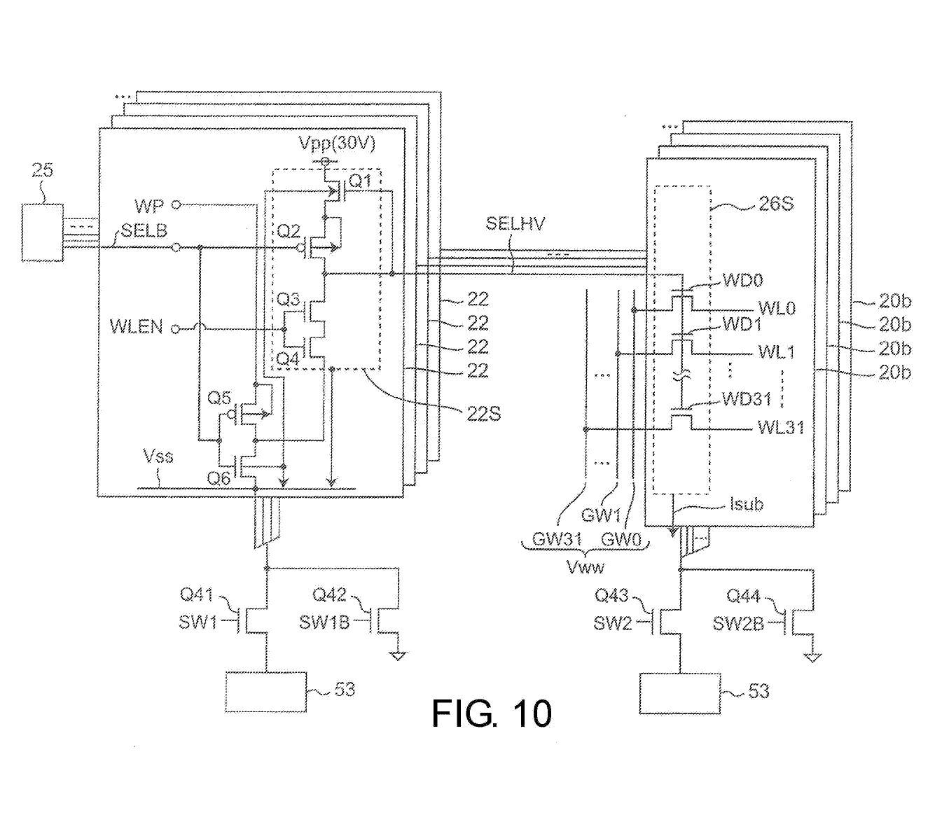

FIG. 9 is a voltage table showing an operation of the measured transistor circuit 51 of FIG. 7A and FIG. 7B. In FIG. 9, when the testing signals T_BD and T_BG of FIG. 7A and FIG. 7B are the power source voltage Vdd, the output voltages Vd and Vg become the ground voltage (0V). On the other hand, when the testing signals T_BD and T_BG are the ground voltage (0V), the output voltages Vd and Vg become the predetermined high voltage HV.

As described above, according to Embodiment 3, the high voltage level shifters 61 and 62 are turned on or off in response to the testing signals T_BD and T_BG, so as to perform control by applying or not applying the predetermined high voltage HV to the drain and the gate of the MOS transistor Q10. Accordingly, in a situation other than measurement of the breakdown voltage V_BD for the measured MOS transistor Q10 of the measured transistor circuit 51, unexpected current flow to the measured MOS transistor Q10 can be avoided.

### Embodiment 4

FIG. 10 is a circuit diagram showing a configuration example of the transistor testing circuit of Embodiment 4. Here, the test object circuit is the row decoder 22 and the transistors WD0-WD31 of the word line driver.

In FIG. 10, the current Ibd flowing to a source-side power source node Vss or a source-side power source line Vss (current detecting node) of the row decoder 22 is measured by the transistor testing circuit of Embodiment 1. In the wafer test, the current Ibd may be measured in a mode of selecting all the blocks of the row decoder 22 or in a mode of deselecting all the blocks. The source-side power source node Vss or the source-side power source line Vss is connected to a ground node via the MOS transistor Q41 controlled based on the switching control signal SW1 and via the high voltage protection circuit 52 and the current detecting circuit 53 of Embodiment 1, and is grounded via the MOS transistor Q42 controlled based on the switching control signal SW1B. For example, the substrate tap 22S of the row decoder 22 may be connected to the ground node Vss, for example, for measuring the current Ibd. In addition, in FIG. 10, the source-side power source node Vss or the source-side power source line Vss of multiple blocks is connected with the substrate tap 22S, and the connection terminal is used as the current detecting node to detect the current. The source-side power source node Vss or the source-side power source line Vss may also be a ground-side power source node Vss or a ground-side power source line Vss. Moreover, the switching control signals SW1 and SW1B are inputted from the testing controller 50 or the external testing device, the same as Embodiment 3, and the switching control signal SW1B is an inverted signal of the switching control signal SW1. In FIG. 10, the current detecting circuit 53 is connected not via the high voltage protection circuit 52 of Embodiment 1 for the reason that the high voltage is less likely to reach until the source-side power source node Vss or the source-side power source line Vss from the point of view of the circuit and measurement range. Certainly, the current detecting circuit 53 may also be connected via the high voltage protection circuit 52.

The multiple blocks of the row decoder 22 are selected according to a block selecting signal SELB (low active) from a block selecting signal generating circuit 25, and a block selecting signal SELHV (high voltage HV) generated from the row decoder 22 is connected to each gate of the word line driver transistors WD0-WD31 of the selected memory cell block 20b. Here, in order to measure a substrate current Isub flowing to the substrate tap 26S of the silicon substrate formed with the word line driver transistors WD0-WD31, the substrate tap 26S is connected to the current detecting circuit 53 of Embodiment 1 via the MOS transistor Q43 controlled based on the switching control signal SW2 and is grounded via the MOS transistor Q44 controlled based on the switching control signal SW2B, i.e. the inverted signal of the switching control signal SW2. In addition, the switching control signals SW2 and SW2B are inputted from the testing controller 50 or the external testing device, the same as Embodiment 3.

Further, in FIG. 10, the current of the substrate tap 26S of the word line drivers WD0-WD31 are measured. However, depending on the configuration of the word line driver circuit, the current of the P well tap or the source of the MOS transistor may be measured. If the transistors of the word line driver transistors WD0-WD31 have the structure of FIG. 5B, the current of the P well tap is measured, and since the high voltage may come down to, it is preferable to connect the current detecting circuit 53 via the high voltage protection circuit 52.

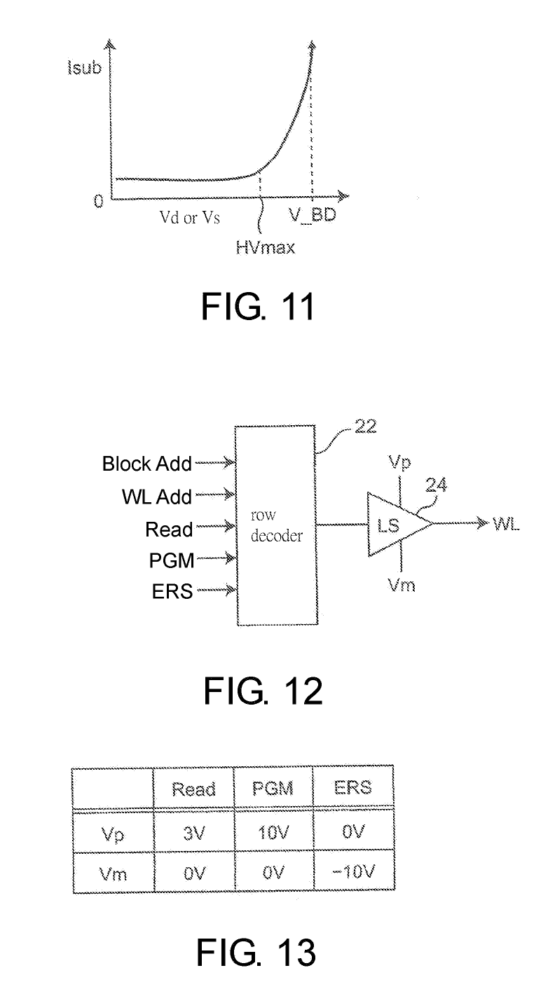

FIG. 11 is a diagram showing a measuring method of the breakdown voltage of the transistor testing circuit of FIG. 10. In FIG. 11, as the drain voltage Vd or the gate voltage Vg applied to the measured MOS transistor Q10 becomes close to the breakdown voltage V_BD, for example, the substrate current Isub flowing to the substrate tap 26S of FIG. 10 increases exponentially. Thus, the breakdown voltage of the word line driver transistors WD0-WD31, i.e. the measured MOS transistor, can be measured by measuring the substrate current Isub, and thereby, the maximum high voltage Hvmax (referring to an allowable maximum voltage that is lower than the breakdown voltage V_BD by a predetermined margin) can be determined.

In the transistor testing circuit configured in the aforementioned manner, by setting the MOS transistor Q41 to ON to detect the current Ibd flowing to the source-side power source node Vss or the source-side power source line Vss of the row decoder 22, the breakdown voltage V_BD of the measured transistor circuit of the row decoder 22 can be measured. In addition, by measuring the substrate current Isub at the P well tap of the word line driver transistors WD0-WD31, for example, the maximum high voltage Hvmax (the allowable maximum voltage that is lower than the breakdown voltage V_BD by the predetermined margin) of the word line driver transistors WD0-WD31, i.e. the measured MOS transistor, can be determined.

### Embodiment 5

FIG. 12 is a block diagram showing a configuration example of the word line driver of the NOR type flash memory of Embodiment 5. Here, the word line driver is the test object circuit.

In the NOR type flash memory, a positive voltage and a negative voltage are used for programming (writing data) and erasing data, and the voltage value is reduced and the gate oxide film is thinned in order to achieve higher reading performance. In FIG. 12, the word line driver of the NOR type flash memory includes the row decoder 22 and the level shifter 24 supplied with power source voltages Vp and Vm. In addition, the signals inputted to the row decoder 22 are described below.

(1) Block Add: block address designating and adding signal
(2) WL Add: word line address designating and adding signal
(3) Read: data reading signal
(4) PGM: data programming signal
(5) ERS: data erasing signal

FIG. 13 is a power source voltage table showing an operation of the word line driver of FIG. 12. As shown in FIG. 13, the power source voltages Vp and Vm are set according to data reading (Read), data programming (PGM), and data erasing (ERS).

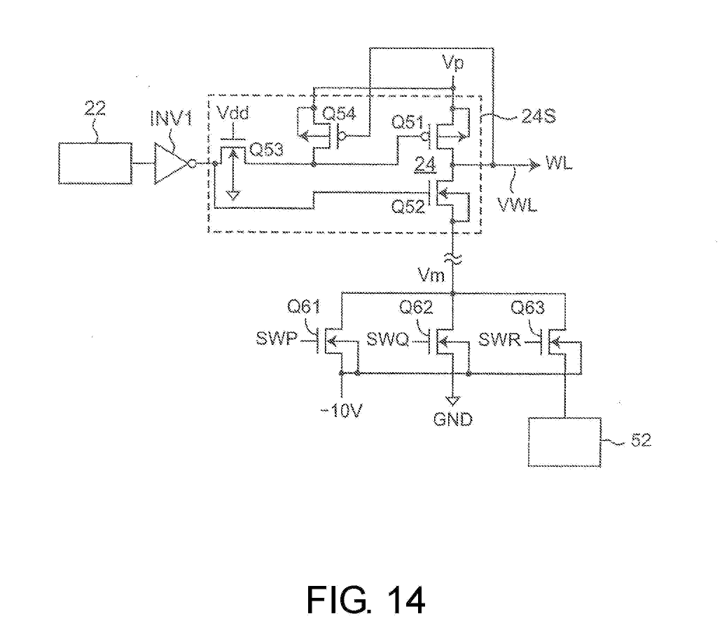

FIG. 14 is a circuit diagram showing a configuration example of the transistor testing circuit of the word line driver of FIG. 12. In FIG. 14, the level shifter 24 includes MOS transistors Q51-Q54. A word line selecting signal from the row decoder 22 is inverted by an inverter INV1, and the inverted signal is inputted to the level shifter 24 for controlling the operation of the level shifter 24. Here, the MOS transistor Q53 is a high voltage blocking transistor, and the MOS transistor Q54 is disposed for using the high voltage Vp to pull up the gate voltage for the MOS transistors Q51. The power source voltage terminal Vm is connected to −10V via the switching MOS transistor Q61 controlled based on the switching control signal SWP, grounded via the switching MOS transistor Q62 controlled based on the switching control signal SWQ, and connected to the transistor testing circuit of Embodiment 1 via the switching MOS transistor Q63 controlled based on the switching control signal SWR and via the high voltage protection circuit 52.

In the programming mode, when all the word lines in the level shifter 24 are deselected, the MOS transistor Q51 is set to OFF and the MOS transistor Q52 is set to ON, such that the word line voltage VWL becomes 0V and a voltage of 10V is applied between the source and drain of the PMOS transistor Q51. On the other hand, when all the word lines are selected, the MOS transistor Q51 is set to ON and the MOS transistor Q52 is set to OFF, such that the word line voltage VWL becomes 10V and a voltage of 10V is applied between the source and drain of the NMOS transistor Q52. That is, a leakage current of the word line driver flows to the line of the power source voltage Vm line. Therefore, by connecting the current detecting circuit 53 of Embodiment 1 to the power source voltage Vm line, the same as the NAND type flash memory, the breakdown voltage of the PMOS transistor or the NMOS transistor of the word line driver in the programming mode can be measured and thereby the maximum value HVmax of the high voltage can be determined.

In the transistor testing circuit configured in the aforementioned manner, when erasing data, by setting the power source voltage Vp to satisfy Vp=0V and turning on only the MOS transistor Q61 of the three MOS transistors Q61-Q63, the word line driver can be set to a data erasing mode. Moreover, when reading data or programming data, Vp is set equal to 3V or 10V (Vp=3 V or 10 V) and only the MOS transistor Q62 of the three MOS transistors Q61-Q63 is turned on, so as to set the word line driver to the respective mode. Thus, when testing the transistor, by turning on only the MOS transistor Q63 of the three MOS transistors Q61-Q63 to connect to the transistor testing circuit of Embodiment 1, the predetermined current detection can be performed to measure the breakdown voltage V_BD.

In FIG. 14, the current from the terminal of the power source voltage Vm of the source-side line of the level shifter 24 is measured. However, the invention is not limited thereto. The substrate tap 24S of the level shifter 24 may be connected to the drain of the MOS transistor Q63 for carrying out the transistor test.

### Embodiment 6

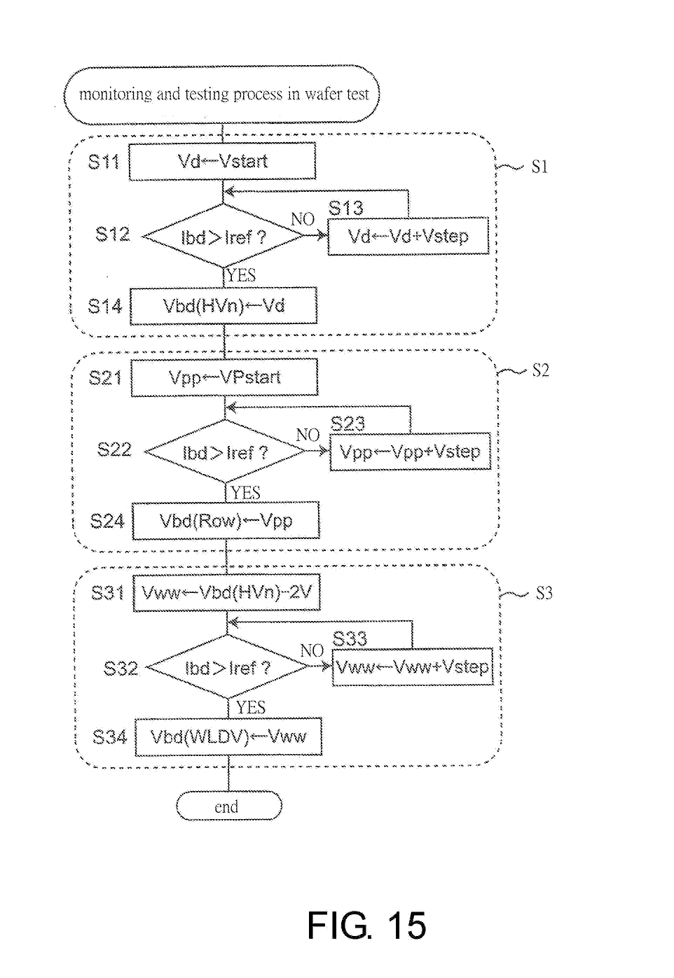

FIG. 15 is a flowchart showing a monitoring and testing process in the wafer test of Embodiment 6. In FIG. 15, the monitoring and testing process includes:

(1) a breakdown voltage detecting process for the high voltage transistor (S1);
(2) a breakdown voltage detecting process (S2) for the row decoder; and
(3) a breakdown voltage detecting process for the word line driver (S3). Moreover, the processes S1-S3 may be executed individually.

In the flowchart of FIG. 15, the breakdown voltage V_BD in the wafer test is measured. The write voltage Vww and the power source voltage Vpp that are actually used are determined based on the measured breakdown voltage V_BD.

In the breakdown voltage detecting process for the high voltage transistor (S1), the setting value of the drain voltage Vd of the measured transistor Q10 is set to a start value Vstart in Step S11 for the transistor testing circuit of FIG. 3 to determine whether the detecting current Ibd>the reference current Iref. If the result is “YES”, the procedure moves on to Step S14. If the result is “NO”, the procedure moves on to Step S13 to increase the setting value of the drain voltage Vd by a predetermined step value Vstep, the determination of whether the detecting current Ibd>the reference current Iref is performed by the transistor testing circuit of FIG. 3, and the process is repeated. In Step S14, the current setting value of the drain voltage Vd is set to the breakdown voltage Vbd (HVn) of the high voltage transistor HVn and the procedure moves on to the next process (S2).

In the foregoing process (S1), the breakdown voltage Vbd of the high voltage transistor (HVn), e.g. the MOS transistor Q10, is measured. Moreover, in the wafer test, the source current and the substrate current are measured in a combination condition of the gate voltage Vg=0V.

In the breakdown voltage detecting process for the row decoder (S2), when all the blocks are deselected, for example, the gate voltage of the transistor Q1 is 0V and the drain is applied with the high voltage Vpp. Thus, the breakdown voltages of all the transistors Q1 of the row decoder 22 can be measured (determined by the weakest transistor). The write voltage Vww is set to satisfy Vww=Vbd(HVn)−3V, for example.

In Step S21, the setting value of the power source voltage Vpp of the measured transistor Q1 is set to a start value VPstart for the transistor testing circuit of FIG. 3 to determine whether the detecting current Ibd>the reference current Iref. If the result is “YES”, the procedure moves on to Step S24. If the result is “NO”, the procedure moves on to Step S23 to increase the setting value of the power source voltage Vpp by a predetermined step value Vstep, and the determination of whether the detecting current Ibd>the reference current Iref is performed by the transistor testing circuit of FIG. 3, and the process is repeated. In Step S24, the current setting value of the power source voltage Vpp is set to the breakdown voltage Vbd (Row) of the row decoder and the procedure moves on to the next process (S3).

In the foregoing process (S2), the breakdown voltage Vbd of the row decoder is measured. The measured object is the high voltage depletion type NMOS transistor of the row decoder, for example. In a condition of not selecting blocks, the ground current is measured. The current may also be combined with the source current and the substrate current, as Embodiment 4 and Embodiment 5.

In the breakdown voltage detecting process for the word line driver (S3), when all the word lines are deselected, the gate of all the word line driver transistors is 0V and the drain is applied with the write voltage Vww. Therefore, the breakdown voltages of all the word line driver transistors of the row decoder 22 can be measured (determined by the weakest transistor). The power source voltage Vpp is set to satisfy Vpp=Vbd(Row)−1V, for example. In Step S31, the setting value of the write voltage Vww of the word line driver is set to Vbd(HVn)−2V for the transistor testing circuit of FIG. 3 to determine whether the detecting current Ibd>the reference current Iref. If the result is “YES”, the procedure moves on to Step S34. If the result is “NO”, the procedure moves on to Step S33 to increase the setting value of the write voltage Vww by a predetermined step value Vstep, the determination of whether the detecting current Ibd>the reference current Iref is performed by the transistor testing circuit of FIG. 3, and the process is repeated. In Step S34, the current setting value of the write voltage Vww is set to the breakdown voltage Vbd (WLDV) of the word line driver, and the monitoring and testing process ends.

In the foregoing process (S3), the breakdown voltage Vbd of the word line driver is measured. Based on the condition that the gate voltage Vg satisfies Vg=0 V and the drain voltage Vd satisfies Vd=Vww, the substrate current is measured as in Embodiment 4 and Embodiment 5.

In terms of the aforementioned breakdown voltage detecting processes (S2 and S3) for the circuits of the row decoder and the word line driver, for the evaluation, there is no problem in detecting the breakdown voltage under the current at the level that actually causes breakdown; however, it's problems in the wafer test for product delivery inspection test. Damage may occur in reality. Therefore, for the current Ibd that serves as the determination reference and the reference current Iref corresponding thereto, at least two types of values are applicable, which are the reference value for evaluation and the reference value for inspection.

### Embodiment 7

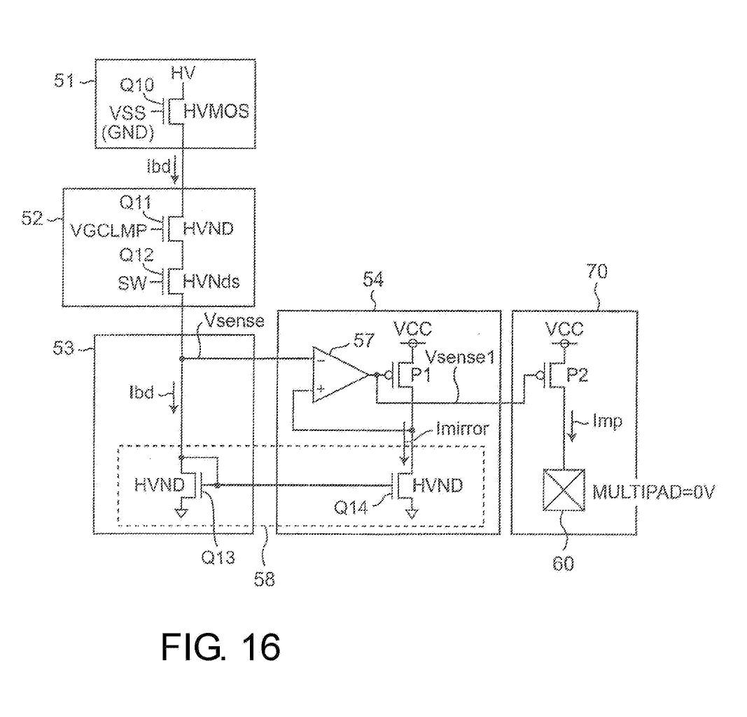

FIG. 16 is a circuit diagram showing a configuration example of the transistor testing circuit of Embodiment 7. The transistor testing circuit of Embodiment 7 is different from the transistor testing circuit of FIG. 3 in the following aspects.

(1) A current outputting circuit 70 is provided in place of the reference bias current generating circuit 56 and the comparator circuit 55. The current outputting circuit 70 includes a MOS transistor P2 whose gate is applied with the control voltage Vsense1 and a test pad 60, and makes a measured current Imp corresponding to the current Ibd mirrored according to the control voltage Vsense1 to flow to the test pad 60. In the test mode, the measured current Imp is outputted to the external testing device via a selector circuit (not shown) to be measured.
(2) A ratio of the sizes of the MOS transistors Q13 and Q14 of the current mirror circuit 58 is set to 1:N (N≧1). By setting the value of N to be greater than 1, a larger measured current Imp, as compared with the case of the size ratio 1:1, can be obtained.

### Embodiment 8

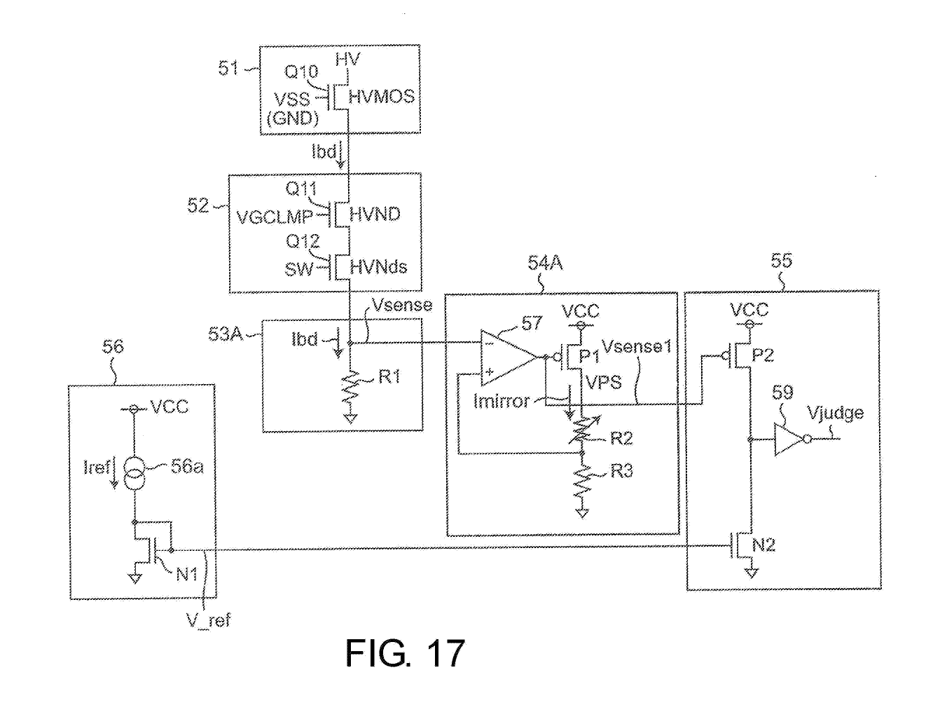

FIG. 17 is a circuit diagram showing a configuration example of the transistor testing circuit of Embodiment 8. The transistor testing circuit of Embodiment 8 is different from the transistor testing circuit of FIG. 3 in the following aspects.

(1) A current detecting circuit 53A is provided in place of the current detecting circuit 53 and a load resistor R1 is disposed in place of the MOS transistor Q13.
(2) A current mirror voltage outputting circuit 54A is provided in place of the current mirror voltage outputting circuit 54. Here, a variable resistor R2 and a load resistor R3 are disposed in place of the MOS transistor Q14. The drain voltage VPS of the MOS transistor P1 is divided by the resistors R2 and R3, and the divided voltage is fed back to a non-inverted input terminal of the differential amplifier 57. Here, by changing the resistance value of the variable resistor R2, the voltage VPS can be set to a value that is optimal for correctly mirroring the current Ibd. By properly setting the resistance values of R1 and R3, the mirror current Imirror can be changed properly as shown by the equation below.

Imirror=Ibd×R1/R3

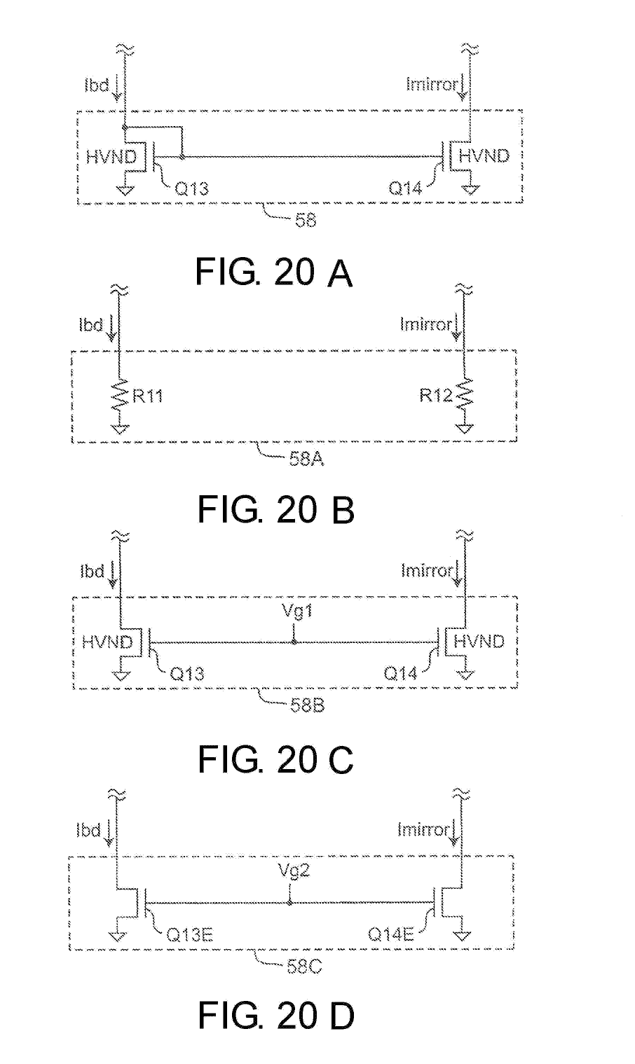

In the above embodiment, the load resistor R1 is used. However, the invention is not limited thereto. According to the prior art, it is also possible to use a diode-connected depletion type transistor, or an enhancement type MOS transistor or a depletion type MOS transistor applied with a predetermined gate voltage for making the detecting voltage Vsense, i.e. the drain voltage, around 0V when the current Ibd flows. The modified examples are described below with reference to FIG. 20A to FIG. 20D.

### Embodiment 9

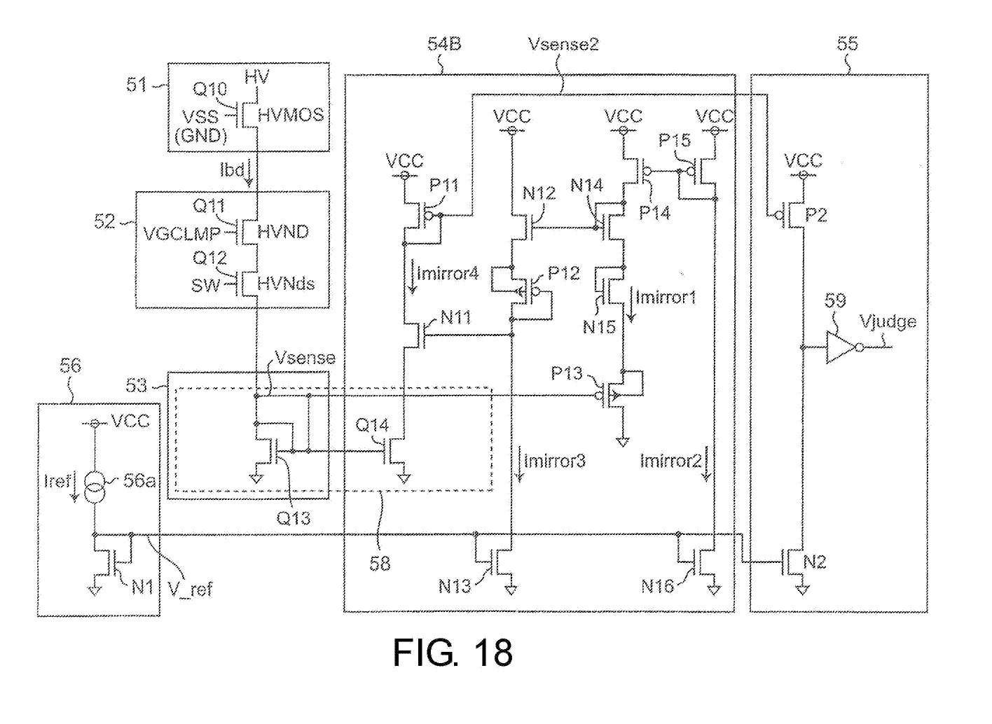

FIG. 18 is a circuit diagram showing a configuration example of the transistor testing circuit of Embodiment 9. The transistor testing circuit of Embodiment 9 is different from the transistor testing circuit of FIG. 3 in the following aspects. A current mirror voltage outputting circuit 54B is provided in place of the current mirror voltage outputting circuit 54. Here, the current mirror voltage outputting circuit 54B does not include the differential amplifier 57 but includes the following four mirror current generating circuits.

(1) A first mirror current generating circuit respectively includes a series circuit of diode-connected MOS transistors N14, N15, and P13 and makes the mirror current Imirror1 corresponding to Imirror2, i.e. the mirror current of the reference current Iref, to flow.
(2) A second mirror current generating circuit includes a series circuit of MOS transistors P15 and N16 and makes the mirror current Imirror2 corresponding to the reference current Iref to flow.
(3) A third mirror current generating circuit includes a series circuit of MOS transistors N12, P12, and N13 and makes a mirror current Imirror3 corresponding to the reference current Iref to flow.
(4) A fourth mirror current generating circuit includes a series circuit of MOS transistors P11, N11, and Q14 and makes a mirror current Imirror4 corresponding to the detecting current Ibd to flow.
In addition, the reference voltage V_ref is applied to the gates of the MOS transistors N13, N16, and N2 from the reference bias current generating circuit 56.

In the transistor testing circuit configured in the aforementioned manner, the source voltage of the MOS transistor P13 becomes Vsense+Vtp (Vtp is a threshold value of the P channel transistor), and Vtn (Vtn is a threshold value of the N channel transistor) is added to the source voltage of the MOS transistor P13, such that the drain voltage of the MOS transistor N15 becomes Vsense+Vtp+Vtn. The gate voltage of the MOS transistor N12 and the gate voltage of the MOS transistor N14 are shared. Therefore, the source voltage of N12 also becomes Vsense+Vtp+Vtn, the same as the source voltage of N14. The drain voltage of the MOS transistor P12 becomes Vsense+Vtn obtained by subtracting Vtp. The source voltage of the MOS transistor N11 becomes Vsense obtained by further subtracting Vtn. Thus, the mirror current Imirror4 flows corresponding to the detecting current Ibd, and the mirror voltage Vsense 2 is generated at the drain of the MOS transistor P11 corresponding to the mirror current Imirror 4. That is, the mirror voltage Vsense2 corresponding to the detecting current Ibd is applied to the gate of the MOS transistor P2. Therefore, the same as Embodiment 1, the comparator circuit 55 compares the detecting current Ibd with the reference current Iref and outputs the inverted comparison result signal Vjudge.

### Embodiment 10

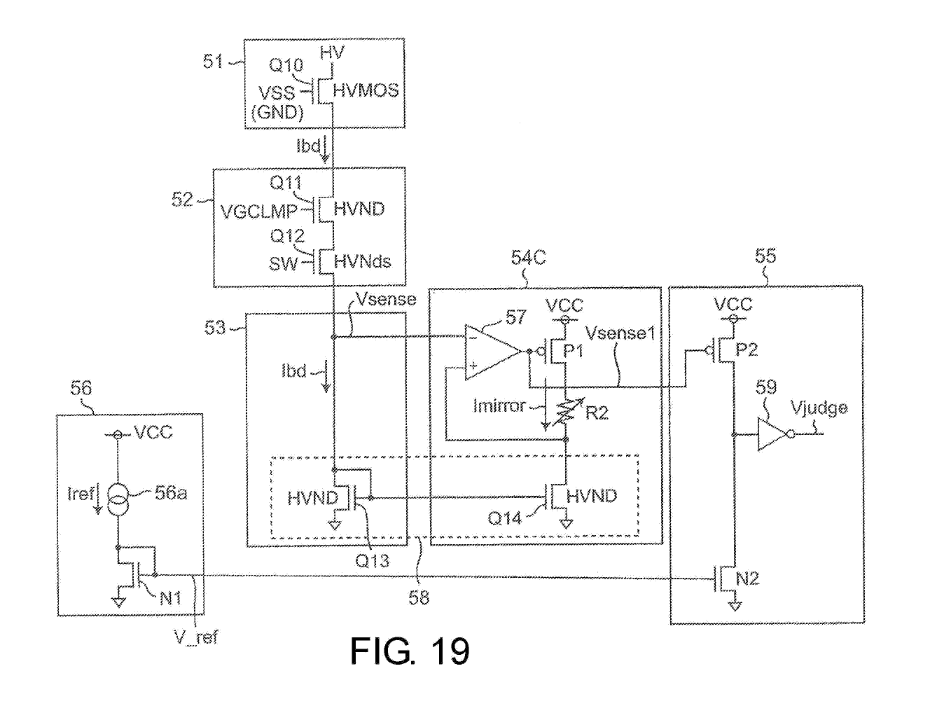

FIG. 19 is a circuit diagram showing a configuration example of the transistor testing circuit of Embodiment 10. The transistor testing circuit of Embodiment 10 is different from the transistor testing circuit of FIG. 3 in the following aspects.

(1) A current mirror voltage outputting circuit 54C is provided in place of the current mirror voltage outputting circuit 54. Specifically, the drain of the PMOS transistor P1 is connected to the drain of the MOS transistor Q14 and the non-inverted input terminal of the differential amplifier 57 via the variable resistor R2 that adjusts the mirror current Imirror.

According to Embodiment 10 configured above, in addition to the effects of the transistor testing circuit of Embodiment 1, the mirror current Imirror corresponding to the detecting current Ibd can be adjusted by the variable resistor R2.

### Modified Example

FIG. 20A is a circuit diagram showing a configuration example of the current mirror circuit 58 of FIG. 3, FIG. 16, and FIG. 19. FIG. 20B is a circuit diagram showing a configuration example of the current mirror circuit 58A of Modified Example 1. In comparison with FIG. 20A, the current mirror circuit 58A of Modified Example 1 is characterized in including load resistors R11 and R12 respectively in place of the MOS transistors Q13 and Q14, and by adjusting the resistance values of the load resistors R11 and R12, the relationship between the detecting current Ibd and the mirror current Imirror can be adjusted.

FIG. 20C is a circuit diagram showing a configuration example of the current mirror circuit 58B of Modified Example 2. In comparison with the current mirror circuit 58 of FIG. 20A, the current mirror circuit 58B of Modified Example 2 is characterized in that: a predetermined gate voltage Vg1 is applied to the gates of the MOS transistors Q13 and Q14, such that the detecting current Ibd and the mirror current Imirror respectively become the predetermined current values.

FIG. 20D is a circuit diagram showing a configuration example of the current mirror circuit 58C of Modified Example 3. In comparison with the current mirror circuit 58B of FIG. 20C, the current mirror circuit 58C of Modified Example 3 is characterized in including enhancement type MOS transistors Q13E and Q14E in place of the depletion type MOS transistors Q13 and Q14. Here, a predetermined gate voltage Vg2 is applied to the gates of the MOS transistors Q13E and Q14E, such that the detecting current Ibd and the mirror current Imirror respectively become the predetermined current values.

The above embodiments describe the internal power source voltage generating circuit for a semiconductor non-volatile memory apparatus, such as a flash memory. However, the invention is not limited thereto. The invention is also applicable to various semiconductor memory apparatuses, such as semiconductor volatile memory apparatuses, e.g. dynamic random access memory (DRAM) and synchronous dynamic random access memory (SDRAM), or semiconductor apparatuses, such as a semiconductor integrated circuit with a processor, etc. In addition, the flash memory is not limited to the NAND type, and the flash memory may also be a NOR type flash memory. Furthermore, Embodiments 6-9 may also be applied to Embodiments 1-5.

As described in detail above, according to the transistor testing circuit of the invention, with the transistor testing circuit that tests the transistor disposed in the semiconductor apparatus, the breakdown voltage of the transistor included in the semiconductor apparatus can be measured and estimated with high precision.

What is claimed is:

1. A transistor testing circuit disposed on a semiconductor chip for measuring a breakdown voltage of a metal-oxide-semiconductor (MOS) transistor, the transistor testing circuit comprising:
a voltage applying apparatus applying a predetermined testing voltage to at least one of a drain, a source, and a gate of the MOS transistor;
a current detecting circuit detecting a detecting current flowing from the MOS transistor to a load circuit when the testing voltage is applied; and
a current mirror voltage outputting circuit generating a mirror current corresponding to the detecting current and outputting the mirror current.

2. The transistor testing circuit according to claim 1, further comprising:
a comparator circuit comparing the mirror current with a predetermined reference current and outputting a comparison result signal.

3. The transistor testing circuit according to claim 1, further comprising:
a test pad outputting the mirror current to an external circuit.

4. The transistor testing circuit according to claim 1, wherein:
the current mirror voltage outputting circuit generates the mirror current corresponding to the detecting current in a ratio of N:1 and outputs the mirror current, wherein N is 1 or more.

5. The transistor testing circuit according to claim 1, further comprising:
a switch circuit connecting at least one of a plurality of transistor terminals comprising the source, the drain, the gate, a well tap, and a substrate tap of the MOS transistor to the load circuit.

6. The transistor testing circuit according to claim 5, wherein:
the switch circuit applies a predetermined applying voltage to at least one of the transistor terminals not connected to the load circuit.

7. The transistor testing circuit according to claim 6, wherein:
the applying voltage is a predetermined value or a ground voltage.

8. The transistor testing circuit according to claim 1, wherein:
the load circuit is a load resistor, a diode-connected depletion type MOS transistor, an enhancement type MOS transistor applied with a predetermined gate voltage, or a depletion type MOS transistor applied with a predetermined gate voltage.

9. The transistor testing circuit according to claim 1, further comprising:
a high voltage protection circuit inserted between the MOS transistor and the load circuit such that a high voltage does not pass through the load circuit.

10. The transistor testing circuit according to claim 9, wherein:
the high voltage protection circuit comprises: a depletion type MOS transistor having a high voltage withstand voltage; and an enhancement type MOS transistor applied with a predetermined gate voltage.

11. The transistor testing circuit according to claim 1, further comprising:
a level shifter operating in response to a predetermined testing signal to output or not output a predetermined high voltage as the testing voltage.

12. A transistor testing circuit disposed between a current detecting node of a predetermined test object circuit of a semiconductor chip and a ground node for measuring a breakdown voltage of the test object circuit, the transistor testing circuit comprising:
a voltage applying apparatus applying a predetermined testing voltage to the test object circuit;
a current detecting circuit detecting a detecting current flowing from the test object circuit to a load circuit when the testing voltage is applied; and
a current mirror voltage outputting circuit generating a mirror current corresponding to the detecting current and outputting the mirror current.

13. The transistor testing circuit according to claim 12, further comprising:
a comparator circuit comparing the mirror current with a predetermined reference current and outputting a comparison result signal.

14. The transistor testing circuit according to claim 12, further comprising:
a test pad outputting the mirror current to an external circuit.

15. The transistor testing circuit according to claim 12, further comprising:
a switch member selectively switching to connect or not connect the current detecting node to the load circuit.

16. The transistor testing circuit according to claim 12, wherein:
the test object circuit is a row decoder.

17. The transistor testing circuit according to claim 16, wherein:
the current detecting node is connected to at least one of a ground-side power source line of the row decoder, and a substrate tap or a well tap of the row decoder.

18. The transistor testing circuit according to claim 12, wherein:
the test object circuit is a word line driver.

19. The transistor testing circuit according to claim 18, wherein:
the current detecting node is connected to at least one of a source, a substrate tap, and a well tap of a MOS transistor of the test object circuit.

20. The transistor testing circuit according to claim 12, wherein:
the load circuit is a load resistor, a diode-connected depletion type MOS transistor, an enhancement type MOS transistor applied with a predetermined gate voltage, or a depletion type MOS transistor applied with a predetermined gate voltage.

21. The transistor testing circuit according to claim 12, further comprising:
a high voltage protection circuit inserted between the current detecting node and the load circuit such that a high voltage does not pass through the load circuit.

22. The transistor testing circuit according to claim 21, wherein:
the high voltage protection circuit comprises: a depletion type MOS transistor having a high voltage withstand voltage; and an enhancement type MOS transistor applied with a predetermined gate voltage.

23. A semiconductor memory apparatus comprising the transistor testing circuit of claim 1.

24. A semiconductor apparatus comprising the transistor testing circuit of claim 1.

25. A transistor testing method, executed by a transistor testing circuit disposed on a semiconductor chip for measuring a breakdown voltage of a MOS transistor, the transistor testing method comprising:
applying a predetermined testing voltage to at least one of a drain and a gate of the MOS transistor;
detecting a detecting current flowing from the MOS transistor to a load circuit when the testing voltage is applied; and
generating a mirror current corresponding to the detecting current and outputting the mirror current.

26. The transistor testing method according to claim 25, further comprising:
comparing the mirror current with a predetermined reference current and outputting a comparison result signal.

27. The transistor testing method according to claim 25, further comprising:
outputting the mirror current to an external circuit via a testing tap.
